(19) United States
(12) Patent Application Publication
(10) Pub. No.: US 2005/0059244 A1
(43) Pub. Date: Mar. 17, 2005

(54) Method for carrying out chemical reactions

(76) Inventors: Karl Lohrberg, Heusenstamm (DE); Dirk Lohrberg, Neu-Isenburg (DE); Henrik Lohrberg, Frankfurt am Main (DE)

Correspondence Address: WENDEROTH, LIND & PONACK, L.L.P., 2033 K STREET N. W., SUITE 800, WASHINGTON, DC, 20006-1021, US

(21) Appl. No.: 10/496,130

(22) PCT Filed: Nov. 26, 2002
(86) PCT No.: PCT/EP02/13295

(30) Foreign Application Priority Data
Nov. 28, 2001 (DE) 101 58 370.2

(51) Int. Cl. H01L 21/302; H01L 21/461

(52) U.S. Cl. 438/689

(57) ABSTRACT

The invention relates to a method for carrying out a chemical reaction, in particular for carrying out a gas-gas or gas-ions reaction, in which, in the absence of a substance catalytically active for the corresponding chemical reaction, an educt or educts is(are) introduced between at least two electric conductors, as well as at the electric conductors an optionally adjustable voltage is applied, through the electric field generated in this way the chemical reaction is initiated and/or the rate of the chemical reaction is increased as well as allowed to proceed and the substance quantity of the product(s) formed is maintained non-proportional to a charge quantity optionally flowing between the electric conductors.

The invention relates to a method for carrying out a chemical reaction, in particular for carrying out a gas-gas or gas-ions reaction.

Especially in the industrial implementation of chemical methods, the goal is generating from the starting materials using the least energy expenditures and selectively obtaining the highest possible yields or the desired product. However, thermodynamically possible reactions proceed spontaneously often so slowly that they can only be realized at all employing catalysts. Due to their property of reducing the activation energy for completing a specific reaction and in this way to increase the rate of chemical reactions, the use of catalysts, compared to carrying out the reaction without catalysts, makes possible carrying out chemical reactions with smaller equipment sizes, lower reaction temperatures and/or lower pressures, which result in cost and energy savings. In many reaction systems different reactions are possible, of which with suitable catalysts a desired reaction can be selectively accelerated. Catalysts are most often oxides with several oxidation stages or reaction potentials.

It is known that the effect of catalysts can be enhanced by promotors, i.e. adaption of the activity of the oxygen to the intended reaction. An increase of the activity and/or of the selectivity of solid-phase catalysts can also be attained under specific conditions by applying an electric field (“Non-Faradaic Electrochemical Modification of Catalysis Activity”, or in short “NEMCA” effect). With the electric field the different potentials of the catalysts can be adapted to the requirements of the particular reaction.

A method based on the “NEMCA” effect for carrying out catalytic reactions or for the oxidation of alkanes and alkenes or for the reduction of carbon monoxide, is disclosed in EP 0 480 116 B1. Between a catalyst, in contact with a solid electrolyte or a porous platinum film, and a counterelectrode, for example of a porous metal or metal oxide, in this method an electric current is applied for generating a change of the catalytic rate via the value of ½ F of the taking-up or splitting-off of ions on the catalyst surface. The solid electrolyte is gas-permeable in contrast to the methods published in the literature regarding the “NEMCA” effect. As the solid electrolyte are employed O₂-conducting materials, for example ZrO₂ containing Y₂O₃, Na⁺-conducting materials, for example β-Al₂O₃, or H⁺- or K⁺-conducting materials. Through this method the catalytic activity of metal or metal oxide catalysts is intended to be increased.

U.S. Pat. No. 6,194,623 B1 discloses a method based on the “NEMCA” effect for the selective hydrogenation of an organic compound having at least one unsaturated group, in which the compound to be hydrogenated and a gas containing hydrogen is brought into contact with a catalyst containing an active material. The catalyst with the active material is separated by a solid electrolyte from a metal substrate forming a reference electrode as well as also a counterelectrode in such manner that in order to maintain a constant potential of the active material a current flows through the solid electrolyte, with a voltage being applied between the catalyst and the metal substrate. As the active material different transition metals, preferably Pd, Pt and Rh, can be employed. The applied voltage is between +5 and −5, preferably between +2 and −2, and especially preferred between +1 and −1 V. This method is said to make possible, for example, reducing from a mixture of ethene and ethyne either selectively ethene to ethane or selectively ethyne to ethene as a function of the process conditions.

A further example of the effect of electric fields on the action of catalysts is known from DE 44 34 141 A1, in which a method is described for the oxidation of alkenes and alkynes, in particular for the production of propylene oxide from propene on the anode side of a gas diffusion cell. As the anode is utilized a gas diffusion electrode, which is structured, in sequence from the inside to the outside, of a synthetic material, for example PVC, a lead sheet provided with a gas inflow and gas outflow line as well as a conductive woven graphite textile coated with a commercially available catalyst based on platinum and, as the cathode, for example sheet lead. For carrying out the method a sulfuric acid solution for example is electrolyzed at 59° C. and at an applied voltage between the electrodes of 2.3 V.

Lastly, from EP 0 987 348 A1 is known a method for the electrochemical partial oxidation of organic compounds, for example for the production of acrylaldehyde from propene, in which as the anode material a special mixed oxide comprising molybdenum and bismuth and as the electrolyte an oxygen ion conducting solid is used. In comparison to a purely catalytic oxidation of propene, this electrochemical reaction is said to produce a yield of acrylaldehyde which is increased by a factor of 2 to 10.

All of the above listed methods must be carried out in complex devices, and the chemical reaction takes place on catalytically active substances in an electric field. Precisely these devices and catalysts contribute considerably to the investment and operating costs of industrial chemical production plants.

The present invention addresses the problem of providing a method for carrying out chemical reactions, which can be carried out simply, under control as well as with low electric energy expenditures and, if possible, at ambient temperatures, which has a high degree of efficiency and which can be completed in the absence of catalytically active substances.

This problem is solved according to the invention for example by making available a method according to patent claim 1.

Within the scope of the present invention it was unexpectedly found that through an electric field not only the activity and/or selectivity of a solid-phase catalyst (“NEMCA” effect) in contact with a solid electrolyte, but also in the absence of a catalytically active substance, the rate of a chemical reaction can be increased due to the setting of the activation voltage of the particular reaction. The electric potential replaces the effect of a catalyst in the method according to the invention. In comparison to the same reaction under identical reaction conditions outside of an electric potential, through the method according to the invention in simple manner the yield and/or the selectivity of the particular reaction can in this way be increased or a reaction which, under the given reaction conditions, does not take place at all outside of an electric field, can be carried out successfully. In contrast to a classic electrochemical reaction, the electric field in the method according to the invention does not act productively since no current flows, i.e. unlike an electrolysis, no conversion occurs of electric energy into chemical energy, nor, unlike a galvanic element or a fuel cell, no conversion of chemical into electric energy takes place. The energy necessary for carrying out an endothermic process was present as latent heat.

Therefore the method according to the invention opens the possibility of carrying out a chemical reaction with low cost expenditures under control and with high efficiency. Further, the use of catalysts, for example of expensive platinum electrodes or complex mixed oxides, can be omitted. By varying the magnitude of the voltage applied between the electric conductors and the change of the field strength resulting therefrom of the electric field, the process of the corresponding chemical reaction can be optimized in simple manner.

The method according to the invention is not limited with respect to the aggregate state of the educts, but can generally be applied for carrying out a chemical reaction of solids and/or liquids and/or gases and/or between solids and gases. With the method according to the invention preferably chemical reactions between two or more gases or between one or several gases and at least one ionogenic compound are carried out.

It is understood that the method according to the invention can equally well be applied for endothermic and exothermic reactions.

Examples of such reactions are the oxidation of hydrocarbons, preferably the oxidation of short-chain alkanes or alkenes and especially preferred the oxidation of ethene to ethylene oxide or the oxidation of propene to propylene oxide, the oxidation of carbohydrates, for example the oxidation of L-sorbose to 2-keto-L-gulonic acid, from which subsequently L-ascorbic acid can be obtained through heat treatment or the oxidation of primary aromatic amines to diazonium salts, from which through subsequent coupling reaction azo pigments can be produced. A further example is the reduction of hydrocarbons, preferably the reduction of short-chain alkenes or alkynes and, especially preferred, the reduction of ethene to ethane or the selective reduction of ethyne to ethene.

With the method according to the invention gas-ions reactions can also be carried out, if an electrolyte is provided between the electric conductors. An example of such a gas-ions reaction is the oxidation of hydroxide ions in an aqueous alkaline solution to hydroperoxide ions. Herein liquid electrolytes are preferably utilized, which, in the devices suitable for carrying out the method according to the invention, can be exchanged faster and more simply in comparison to solid electrolytes. Thereby greater flexibility with respect to conducting the method is attained, since, after a chemical reaction has been completed, the reaction devices can be changed over for carrying out another chemical reaction without great effort.

It should be taken into consideration that in the embodiment of the present invention, in which between the electric conductors an electrolyte, i.e. an ion conductor, is provided, the electric field also acts only catalytically, such that neither, as is the case in an electrolysis, the conversion of electric energy into chemical energy takes place, nor, as is the case in a galvanic element or a fuel cell, a conversion of chemical into electric energy takes place. Accordingly, Faraday's first law according to which the substance quantity of the products formed in a classic electrochemical reaction is proportional to the charge transported by the electrolytes, does not apply to the method according to the invention.

In principle, in the method according to the invention electric conductors known per se are utilized, which have no catalytic activity with respect to the chemical reaction to be carried out. In the embodiment of the present invention, in which between the electric conductors an electrolyte is provided, electric conductors of carbon are preferably utilized, since they are both cost-effective as well as robust. Such a carbon conductor can be comprised for example of sheet lead, on which a fine graphite cloth is disposed. To increase the stability of the electric conductors, the sheet lead provided with a graphite cloth can also be disposed on a synthetic material support, for example a PVC plate.

Experiments have shown that in a large number of the reactions which can be carried out with the method according to the invention, the chemical reaction takes preferably place at the boundary surface of educt and electric conductor or, in the case of gas-ions according to the embodiment of the present invention, in which between the electric conductors an electrolyte is provided, on the three-phase boundary formed of electrolyte, electric conductors and (optionally gaseous) educt. Gaseous educts are therefore preferably conducted via a gas supply line directly to the electric conductor, at which the chemical reactions preferably takes place.

Within the scope of the present invention it could further be found that the reactions according to the invention are promoted by electric conductors with a porous surface.

It is therefore proposed in further development of the inventive concept to provide at least that electric conductor, at which the chemical reaction takes preferably place, with a porous surface or to utilize electric conductors with a porous surface directly. To this end all measures or electric conductors considered suitable by a person skilled in the art are suitable for this purpose. It was especially found to be advantageous to coat that electric conductor, at which the chemical reaction preferably takes place, or both conductors, with a gas diffusion electrode known per se, in particular a gas diffusion electrode with a surface of 50 to 100 m²/g. Equally suitable was found to be employing electric conductors with a large surface, preferably such with a BET surface of more than 1 m²/g, especially preferred of more than 10 m²/g and especially highly preferred of more than 50 m²/g. Raney nickel, especially such with a surface of approximately 1000 m²/g, has also been found useful as electric conductor material.

The magnitude of the voltage, especially DC voltage, to be applied, depends primarily on the type of chemical reaction to be carried out and is preferably calculated from the free reaction enthalpy (ΔG), preferably using the following equation:
U=ΔG/(n·F),
where U denotes the voltage in volt, ΔG the free enthalpy of formation in kcal/mol, n the valency of the reaction (number of electrons shifted per molecule formed) and F Faraday's constant in Asec/mol. If Faraday's constant, which is 96,485.2 Asec/mol, is converted into kcal/mol (by division by 3600 to obtain Ah/mol, as well as subsequent multiplication of the value thus obtained by 0.86 for the conversion, with the assumption that U=1, of kcal into Watt) a value of 23.05 kcal/mol is obtained for the Faraday constant. The preferred voltage to be applied can in so far be calculated from the quotient ΔG/23.05 for monovalent reactions, correspondingly ΔG/46.1 for bivalent reactions or ΔG/n·23.05 for n-valent reactions.

For generating the voltage any voltage source known per se, for example a galvanic element, a rectifier or a DC voltage generator can be employed, from which, by means of a voltage divider, for example a potentiometer, the desired voltage is tapped.

According to a second embodiment of the present invention, in further development of the inventive concept for the solution of the problem described in the introduction, a method according to patent claim 9 is proposed.

In this method the electrolysis process applied industrially for obtaining a multiplicity of chemical substances is combined with the method according to the invention for carrying out a chemical reaction in an electric field. This has the advantage that the method can be carried out with minor modifications in the well-tested electrolysis devices optimized with respect to resistance and economy.

It should be taken into consideration that in this method according to the invention the chemical reaction proceeding parallel to or quasi “against the background” of an electrolysis reaction is also only activated by the electric field without, as is the case in an electrolysis, a conversion of electric energy into chemical energy taking place, or, as in the case of a galvanic element or a fuel cell, a conversion of chemical into electric energy. Accordingly, the first law of Faraday, according to which the substance quantity of the products formed in a classic electrochemical reaction is proportional to the charge transported by the electrolytes, cannot be applied to the chemical reaction proceeding parallel to the electrolysis reaction.

Through the reactions proceeding in parallel, i.e. the chemical reaction catalyzed by the electric field and the electrolysis reaction, the same products are preferably obtained. Since the reaction activated by the electric potential, in contrast to the electrolysis, does not consume electric energy, with the method according to the invention, compared to the purely electrolytic generation of the products, an efficiency of more than 100% is attained.

By selecting the reaction parameters such that, while a voltage sufficient for maintaining the corresponding electrolysis reaction is applied at the electrodes, but the magnitude of current flowing through the electrolyte is so low that only a small conversion of the educts proceeds via the pathway of an electrolysis reaction, efficiencies, again related to the exclusively electrolytic generation of the products, of 1000% and more can be obtained. The voltage is preferably selected such that the substance conversion resulting from the electrolysis reaction, in comparison to the substance conversion through the chemical reaction proceeding parallel to the electrolysis, is low and, with respect to the total substance conversion, is preferably less than 10% especially preferred less than 5% and especially highly preferred less than 2%.

The method according to the second embodiment of the present invention is also not limited with respect to the aggregate state of the educts, such that all of those chemical reactions can be carried out as in the method according to the first embodiment of the present invention.

Not conclusively and only by example, examples will be listed of the chemical oxidation of hydrocarbons, preferably the oxidation of short-chain alkanes or alkenes and especially preferred the oxidation of ethene to ethylene oxide or the oxidation of propene to propylene oxide, the oxidation of carbohydrates, for example the oxidation of L-sorbose to 2-keto-L-gulonic acid, from which L-ascorbic acid can subsequently be obtained through heat treatment, the oxidation of primary aromatic amines to diazonium salts, from which through a subsequent coupling reaction azo pigments can be produced, the reduction of hydrocarbons, preferably the reduction of short-chain alkenes or alkynes and especially preferred the reduction of ethene to ethane or especially preferred the reduction of ethene to ethane [SIC] or the selective reduction of ethyne to ethene.

As is the case with the methods according to the first embodiment of the present invention, in the method according to the second embodiment electric conductors known per se are employed, which, with respect to the chemical reaction to be carried out, have no catalytic activity. In the second embodiment are preferably also used electric conductors of carbon.

Further, one or both electrodes are provided with a porous surface or electrodes with porous surface are utilized directly, and all measures or electrodes considered suitable for this purpose by a person skilled in the art are suitable. It was in particular found to be advantageous to coat that electrode at which the chemical reaction preferably takes place or both electrodes with a gas diffusion electrode known per se, in particular a gas diffusion electrode with a surface of 50 to 100 m²/g. Equally suitable has been found utilizing electrodes with a large surface, preferably such with a BET surface of more than 1 m²/g, especially preferred of more than 10 m²/g and especially highly preferred of more than 50 m²/g. Raney nickel, in particular such with a surface of, for example, 1000 m²/g has also been found to be useful as electrode material.

The magnitude of the voltage to be applied depends primarily on the type of chemical reaction to be carried out and is preferably calculated from the free enthalpy of reaction (ΔG). Starting from the free reaction enthalpy in kcal/mol, it follows to calculate the voltage in volts according to the above stated calculation from the quotient ΔG/23.05 for monovalent reactions, correspondingly ΔG/46.1 for bivalent reactions or ΔG/n·23.05, for n-valent reactions. To generate the voltage any voltage source known per se can be employed, for example a galvanic element or a capacitor, from which, by means of a voltage divider, for example a potentiometer, the desired voltage is tapped.

Further goals, characteristics, advantages and application feasibilities of the invention can be found in the following description of embodiment examples in conjunction with the drawing. Therein all described and/or graphically depicted characteristics by themselves or in any desired combination form the subject matter of the invention, even independently of their summary in individual claims or their reference back.

In the drawing depict:

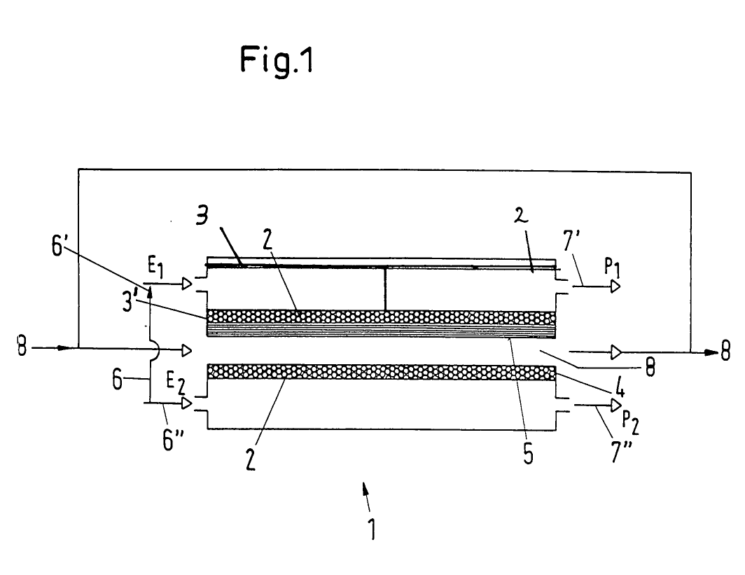

FIG. 1 a device for carrying out the method according to the second embodiment of the present invention for the oxidation of propene with oxygen to propylene oxide and

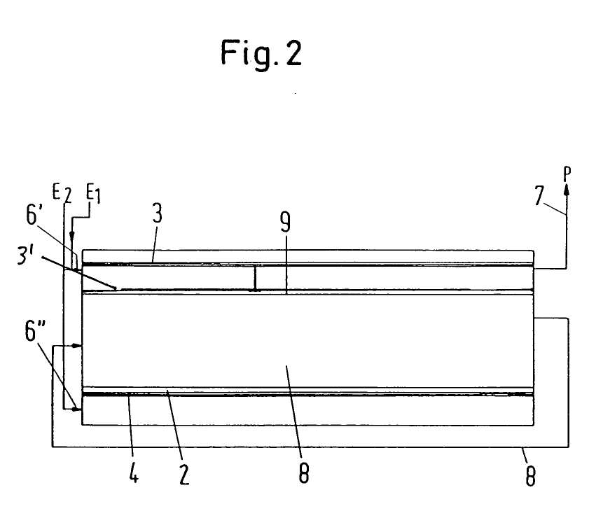

FIG. 2 a device for carrying out the method according to the first embodiment of the present invention for the oxidation of propene with oxygen to propylene oxide.

The device depicted in FIG. 1 is comprised of a horizontally disposed electrolysis cell 1 with an anode 3 coated with a gas diffusion electrode 2, which is electrically connected to a first anode 3′, and a cathode 4 coated with a gas diffusion electrode 2. Both electrodes 3, 4 comprise a conducting expanded metal which, under the specified conditions, is corrosion-resistant and which is disposed in a housing of polypropylene, on which expanded metal is disposed a fine, porous graphite cloth which conducts electric current.

The anode 3 as well as also the cathode 4 are provided with a gas supply line 6 and a gas removal line 7 for supplying the gaseous educts and removing the unreacted gaseous educts E as well as the gaseous products P formed in the reaction. Through a first gas supply line 6′ a mixture of propene and air is supplied to the anode 3 and through a second gas supply line 6″ air is supplied to the cathode 4. The electrolyte 8, divided by a diaphragm 5 into anolyte and catholyte, is an aqueous sodium hydroxide solution which is to some extent moved in circulating flow.

For carrying out the method, at the two electrodes 3, 4 a sufficient high voltage is applied such that the electrolysis reaction starts at the anode 3 and the cathode 4. The electrolysis reaction is composed of the following two partial reactions, namely at the anode:
C₃H_{6(g)}+2OH⁻₍ₐ₎=C₃H₆O_{(g)}+H₂O₍ₗ₎+2e⁻[ε₀=−0.9343 V]
and
at the cathode:
H₂O₍ₗ₎+½O_{2(g)}+2e⁻=2OH⁻₍ₐ₎[ε₀=−0.4015 V].

Parallel to and independently of the oxidation of oxygen through the electrolysis, within the electric field generated between the electrodes 3, 4, and specifically preferred at the anode 3, the following reaction proceeds:
C₃H_{6(g)}+½O_{2(g)}=C₃H₆O_{(g)}
with ΔG=−61.56 kcal/mol corresponding to −1.336 V.

From the free reaction enthalpy (ΔG) of this reaction of −61,56 kcal/mol at 50° C. according to the second law of Faraday is obtained the voltage of 1.336 V necessary for carrying out the reaction according to the present invention.

In contrast to the electrolysis reaction, the last reaction is not an electrochemical reaction, i.e. no electric energy is converted into ohmic heat. Accordingly, the first law of Faraday valid for electrolysis reactions, according to which the substance quantity of the products formed in a classic electrochemical reaction is proportional to the charge transported by the electrolytes, does not apply directly to this chemical reaction.

By selecting the reaction parameters such that while a voltage sufficient for maintaining the corresponding electrolysis reaction is applied at the electrodes 3, 4, but the quantity of current flowing through the electrolyte is so low that only a low substance conversion of propene to propylene oxide proceeds by the pathway of an electrolysis reaction, with this method, relative to the exclusively electrolytic generation of propylene oxide, efficiencies of more than 100% are attained.

In this embodiment example an electrolysis device was utilized, which per se is well-tested. Since the non-electrochemical formation of propylene oxide within the entire reaction volume exposed to the electric field, due to the low current magnitude, preferably takes place at the anode 3, the diaphragm 5 dividing the electrolyte chamber can be omitted.

The same device can also be utilized for producing hydrogen peroxide, if as the electrolyte 8 an aqueous sodium hydroxide solution is used, to the cathode 4, coated with a gas diffusion electrode 2 and, optionally, additionally to the anode 3, oxygen is supplied and to anode 3 water vapor-saturated air is supplied.

The partial reactions of the electrolysis reaction after a sufficient voltage has been applied between the electrodes 3, 4, are in this case at the anode:
2OH⁻₍ₐ₎=H₂O₍ₗ₎+½O_{2(g)}+2e⁻[ε₀=+0.4015 V] or
HO₂⁻₍ₐ₎+OH⁻₍ₐ₎=H₂O₍ₗ₎+O_{2(g)}+2e⁻[ε₀=−0.0651 V]
as well as at the cathode:
2Na⁺₍ₐ₎+O_{2(g)}+H₂O₍ₗ₎+2e⁻=2Na⁺₍ₐ₎+OH⁻₍ₐ₎+HO₂⁻₍ₐ₎[ε₀=−0.1423 V at 30° C.].

Parallel to and independently of the oxidation of oxygen through electrolysis, within the potential field developed between the electrodes 3, 4, and specifically preferably at the anode 3, the following reaction takes place:
H₂O_{(g)}+½O_{2(g)}=H₂O_{2(g)}
with ΔG=+29.329 kcal/mol corresponding to +0.636 V.

The device depicted in FIG. 2 is also comprised of a horizontally disposed reaction cell with two electric conductors 3, 4 and differs from the device shown in FIG. 1 essentially thereby that between the two electric conductors 3, 4 no diaphragm is disposed, the conductor 4 disposed below is coated with a gas diffusion electrode and the conductor 3 has a large inner surface.

For carrying out the method, a voltage is applied at the two conductors 3, 4 by means of a, not shown, DC voltage source sufficiently high for carrying out the reaction with a positive potential at the conductor 3 disposed above and a negative potential at the conductor 4 disposed below. The potential of conductor 3 can be adjusted from the outside as a function of the process conditions or a wire, electrically connected with conductor 3, as a first anode 3′ is immersed into the electrolyte 8. Through a first gas supply line 6′ to the positively poled conductor 3 the two educts are supplied in the form of a propene/air mixture at a pressure sufficiently high, such that a gas phase flows completely around the conductor 3 and between the electrolyte 8 and the gas phase a phase boundary 9 is developed extending over the entire length of the reaction cell. To the negatively poled conductor 4 through a second gas supply line 6″ air is supplied at a pressure above the hydrostatic pressure of the electrolyte, such that the lower portion of the reaction cell is also filled completely by the gas phase up to within the gas diffusion electrode 2 of the conductor 4.

In the upper gas volume within the electric field and specifically preferably at the phase boundary of conductor 3 and gas, the oxidation of the propylene to propylene oxide takes place according to the following formula:
C₃H_{6(g)}+½O_{2(g)}=C₃H₆O_{(g)}
with ΔG=−61.56 kcal/mol corresponding to −1.336 V.

Since the electrolyte 8 is not in contact with the electric conductors 3, 4, in contrast to the method according to the second embodiment of the present invention, no parallel electrochemical reaction takes place in this method.

### List of Reference Symbols

1 Electrolysis cell
2 Gas diffusion electrode
3 Electric conductor, anode
3′ First anode
4 Electric conductor, cathode
5 Diaphragm
6, 6′, 6″ Gas supply line
7, 7′, 7″ Gas removal line
8 Electrolyte
9 Phase boundary (gas-liquid)
E, E₁, E₂ Educt(s)
P, P₁, P₂ Product(s)

1. Method for carrying out a chemical reaction, in particular for carrying out a gas-gas or gas-ions reaction, in which an educt or educts (E) is(are) introduced between at least two electric conductors (3, 4) in the absence of a substance catalytically active for the corresponding chemical reaction, as well as an optionally adjustable voltage is applied at the electric conductors, through the electric field generated in this way the chemical reaction is initiated and/or the rate of the chemical reaction is increased as well as allowed to proceed and the substance quantity of the product(s) (P) formed is maintained non-proportional to a charge quantity optionally flowing between the electric conductors.

2. Method as claimed in claim 1, characterized in that as the chemical reaction is carried out the oxidation of hydrocarbons, preferably the oxidation of short-chain alkanes or alkenes, the oxidation of carbohydrates, the oxidation of aromatic amines or the reduction of hydrocarbons, preferably the reduction of short-chain alkenes or alkynes.

3. Method as claimed in claim 1, characterized in that from ethene and oxygen is formed ethylene oxide, from propene and oxygen propylene oxide, from L-sorbose and oxygen 2-keto-L-gulonic acid, from primary aromatic amines and an oxidation agent diazonium salts, from oxygen and hydroxide ions hydroperoxide ions, from ethene and hydrogen ethane or from ethyne and hydrogen ethene.

4. Method as claimed in claim 1, characterized in that between the electric conductors an electrolyte (8) is introduced.

5. Method as claimed in claim 4, characterized in that between the electric conductors (3, 4) a liquid electrolyte (8) is introduced.

6. Method as claimed in claim 4, characterized in that as the chemical reaction a gas-ions reaction is carried out.

7. Method as claimed in claim 4, characterized in that electric conductors (3, 4) of carbon are utilized.

8. Method as claimed in claim 1, characterized in that the electric conductor (3, 4), at which the chemical reaction preferably takes place, is coated with a gas diffusion electrode (2) or the corresponding electric conductor (3, 4) has a porous surface.

9. Method as claimed in one claim 1, characterized in that a voltage is applied to the corresponding conductors (3, 4), which corresponds to the quotient of ΔG/(n·F), where ΔG denotes the free formation enthalpy, n the valency of the reaction (number of electrons shifted per molecule formed) and F is Faraday's constant.

10. Method for carrying out a chemical reaction, in particular for carrying out a gas-gas or gas-ions reaction, as claimed in claim 4, in which an educt or educts (E) as well as an electrolyte are introduced between at least two electric conductors (3, 4) in the absence of a substance catalytically active for the corresponding chemical reaction, and between the electric conductors (3, 4) an optionally adjustable voltage sufficient for electrolysis to proceed is applied, characterized in that parallel to the electrolysis reaction the chemical reaction is initiated and/or the rate of the chemical reaction is increased or allowed to proceed as well as the substance quantity of the product(s) (P) formed is maintained non-proportional to the charge quantity flowing through the electrolyte (8).

11. Method as claimed in claim 10, characterized in that in the two reactions proceeding in parallel, i.e. the chemical reaction catalyzed by the electric field and the electrolysis reaction, the same products (P) are obtained.

12. Method as claimed in claim 1, characterized in that on the conductors (3, 4) a voltage is applied of a magnitude such that the substance conversion through the electrolysis reaction, relative to the total substance conversion, is less than 10%, especially preferred less than 5% and especially highly preferred less than 2%.

13. Method as claimed in claim 10, characterized in that parallel to the electrolysis reaction one of the reactions listed in claims 1 and 2 takes place.

14. Method as claimed in claim 10, characterized in that electric conductors (3, 4) of carbon are utilized.

15. Method as claimed in claim 10, characterized in that the conductor (3, 4) at which the chemical reaction preferably takes place, is coated with a gas diffusion electrode (2) or the corresponding electric conductor (3, 4) has a porous surface.

16. Method as claimed in claim 10, characterized in that at the corresponding conductors (3, 4) a voltage is applied, which corresponds to the quotient of ΔG/(n·F), where ΔG denotes the free formation enthalpy, n the valency of the reaction (number of electrons shifted per molecule formed) and F is Faraday's constant.
